(19) United States
(12) Patent Application Publication
(10) Pub. No.: US 2022/0415852 A1
(43) Pub. Date: Dec. 29, 2022

(54) SEMICONDUCTOR PACKAGE AND METHOD OF FABRICATING THE SAME

(71) Applicant: Samsung Electronics Co., Ltd., Suwon-si (KR)

(72) Inventor: Hyungu KANG, Hwaseong-si (KR)

(21) Appl. No.: 17/728,118

(22) Filed: Apr. 25, 2022

(30) Foreign Application Priority Data
Jun. 24, 2021 (KR) 10-2021-0082440

(51) Int. Cl. H01L 25/065; H01L 25/00

(52) U.S. Cl. CPC H01L 25/0652; H01L 25/50; H01L 2924/1431; H01L 2924/1434; H01L 24/48

(57) ABSTRACT

A semiconductor package for effectively arranging devices in a limited space is provided. The semiconductor package includes: a substrate; a semiconductor chip formed on the substrate, the semiconductor chip including a center area, a first edge area, which is disposed on a first side of the center area with respect to a first directional axis, and a second edge area, which is disposed on a second side of the center area opposite the first side with respect to the first directional axis; a first spacer formed on the substrate and spaced apart from the semiconductor chip in a direction along the first directional axis; a second spacer formed on the substrate and spaced apart from the semiconductor chip in a direction along the first directional axis; a first chip stack disposed on the semiconductor chip and the first spacer; and a second chip stack disposed on the semiconductor chip and the second spacer. A lowermost chip of the first chip stack is positioned on the first edge area of the semiconductor chip, but not on the center area of the semiconductor chip, and a lowermost chip of the second chip stack is positioned on the second edge area of the semiconductor chip, but not on the center area of the semiconductor chip.

### CROSS-REFERENCE TO RELATED APPLICATION

This application claims priority to Korean Patent Application No. 10-2021-0082440, filed on Jun. 24, 2021 under 35 U.S.C. § 119, the disclosure of which is incorporated herein by reference in its entirety.

### BACKGROUND

### 1. Field

The present disclosure relates to a semiconductor package and a method of fabricating the same.

### 2. Description of the Related Art

In accordance with the recent trends of miniaturization and weight reduction in the field of electronic parts and components, the reduction of semiconductor packages has been occurring. In some cases, the size of packages is limited, but the size and number of devices included in each package increases. Thus, there is a desire to effectively arrange devices in a limited package size.

### SUMMARY

Embodiments of the present disclosure provide a semiconductor package for effectively arranging devices in a limited space.

Embodiments of the present disclosure also provide a method of fabricating a semiconductor package for effectively arranging devices in a limited space.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

According to an embodiment of the present disclosure, a semiconductor package includes: a substrate; a semiconductor chip formed on the substrate, the semiconductor chip including a center area, a first edge area, which is disposed on a first side of the center area with respect to a first directional axis, and a second edge area, which is disposed on a second side of the center area opposite the first side with respect to the first directional axis; a first spacer formed on the substrate and spaced apart from the semiconductor chip in a direction along the first directional axis; a second spacer formed on the substrate and spaced apart from the semiconductor chip in a direction along the first directional axis; a first chip stack disposed on the semiconductor chip and the first spacer; and a second chip stack disposed on the semiconductor chip and the second spacer. A lowermost chip of the first chip stack is positioned on the first edge area of the semiconductor chip, but not on the center area of the semiconductor chip, and a lowermost chip of the second chip stack is positioned on the second edge area of the semiconductor chip, but not on the center area of the semiconductor chip.

According to another embodiment of the present disclosure, a semiconductor package includes: a substrate; a semiconductor chip including a center area, a first edge area, which is disposed on a first side of the center area, and a second edge area, which is disposed on a second side of the center area opposite the first side, the semiconductor chip being in the form of a flip chip; a plurality of bumps disposed between the semiconductor chip and the substrate; an underfill filling space between the substrate and the semiconductor chip; a first support block disposed on the substrate to be spaced apart from a first side of the semiconductor chip; a second support block disposed on the substrate to be spaced apart from a second side of the semiconductor chip opposite the first side; a first chip stack disposed on the first edge area of the semiconductor chip and the first support block; and a second chip stack disposed on the second edge area of the semiconductor chip and the second support block, wherein a distance between a lowermost chip of the first chip stack and a lowermost chip of the second chip stack is greater than ½ of a width of the semiconductor chip, and a distance between the semiconductor chip and the first support block is greater than ½ of a width of the lowermost chip of the first chip stack.

According to still another embodiment of the present disclosure, a method of fabricating a semiconductor package comprises: disposing a semiconductor chip on a substrate, the semiconductor chip including a center area, a first edge area, which is disposed on a first side of the center area, and a second edge area, which is disposed on a second side of the center area opposite the first side; disposing first and second spacers on the substrate to be spaced apart from the semiconductor chip; and disposing a first chip stack on the semiconductor chip and the first spacer and disposing a second chip stack on the semiconductor chip and the second spacer. Disposing the first chip stack on the semiconductor chip and the first spacer and disposing a second chip stack on the semiconductor chip and the second spacer includes positioning a first lowermost chip of the first chip stack on the first edge area of the semiconductor chip, but not on the center area of the semiconductor chip, and positioning a second lowermost chip of the second chip stack on the second edge area of the semiconductor chip, but not on the center area of the semiconductor chip.

Other features and embodiments may be apparent from the following detailed description, the drawings, and the claims.

### BRIEF DESCRIPTION OF THE DRAWINGS

The above and other embodiments and features of the present disclosure will become more apparent by describing in detail embodiments thereof with reference to the attached drawings, in which:

FIG. 1 is a plan view of a semiconductor package according to a first embodiment of the present disclosure;

FIG. 2 is a cross-sectional view taken along line II-II of FIG. 1, according to some embodiments;

FIG. 3 is an enlarged cross-sectional view of an area A of FIG. 2, according to some embodiments;

FIG. 4 is an enlarged cross-sectional view of an area B of FIG. 2, according to some embodiments;

FIG. 5 is a cross-sectional view of a semiconductor package according to a second embodiment of the present disclosure;

FIG. 6 is a cross-sectional view of a semiconductor package according to a third embodiment of the present disclosure;

FIG. 7 is a cross-sectional view of a semiconductor package according to a fourth embodiment of the present disclosure;

FIG. 8 is a cross-sectional view of a semiconductor package according to a fifth embodiment of the present disclosure;

FIG. 9 is a plan view of a semiconductor package according to a sixth embodiment of the present disclosure;

FIG. 10 is a cross-sectional view of a semiconductor package according to a seventh embodiment of the present disclosure;

FIG. 11 is a cross-sectional view of a semiconductor package according to an eighth embodiment of the present disclosure;

FIG. 12 is a plan view of the semiconductor package of FIG. 11;

FIG. 13 is a cross-sectional view of a semiconductor package according to a ninth embodiment of the present disclosure;

FIG. 14 is a cross-sectional view of a semiconductor package according to a tenth embodiment of the present disclosure;

FIG. 15 is a cross-sectional view of a semiconductor package according to an eleventh embodiment of the present disclosure;

FIG. 16 is a block diagram illustrating a method of fabricating the semiconductor package according to the first embodiment;

FIGS. 17 through 19 are cross-sectional views illustrating intermediate steps of the method of FIG. 16;

FIG. 20 is a block diagram of a memory card including a semiconductor package according to some embodiments of the present disclosure; and

FIG. 21 is a block diagram of an information processing system to which a semiconductor package according to some embodiments of the present disclosure is applied.

### DETAILED DESCRIPTION

Embodiments of the present disclosure will hereinafter be described with reference to the accompanying drawings. Like reference numerals indicate like elements, and thus, detailed descriptions thereof will be omitted.

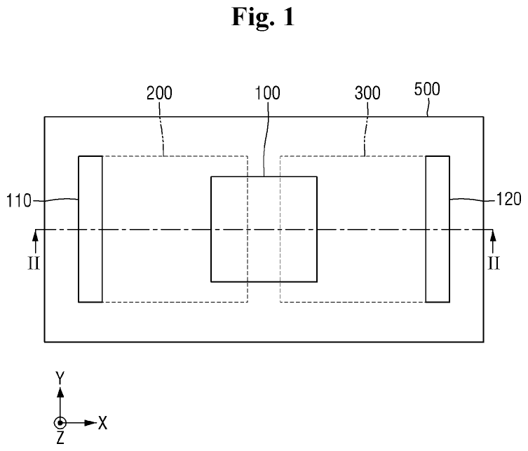

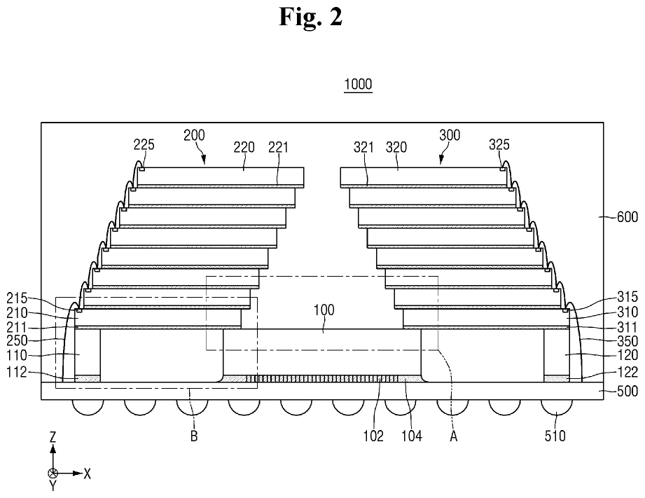

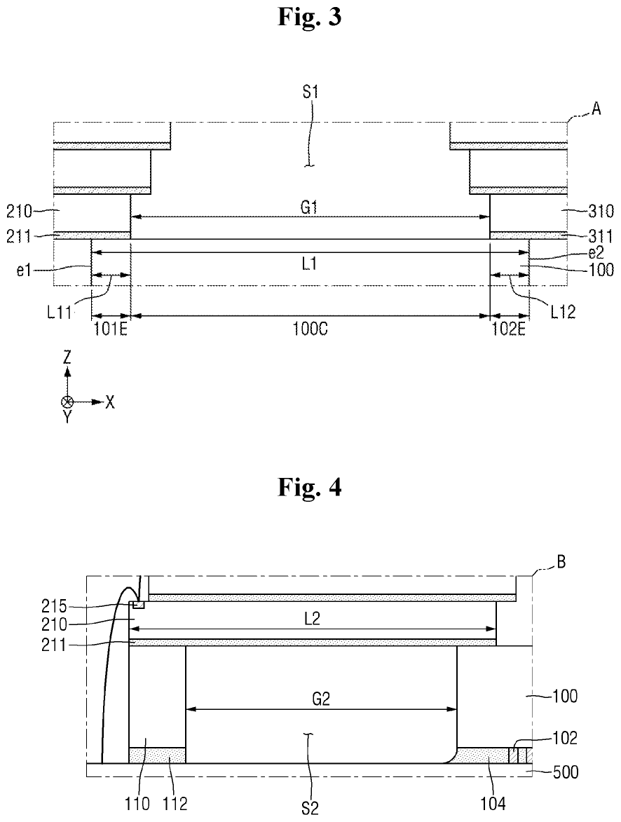

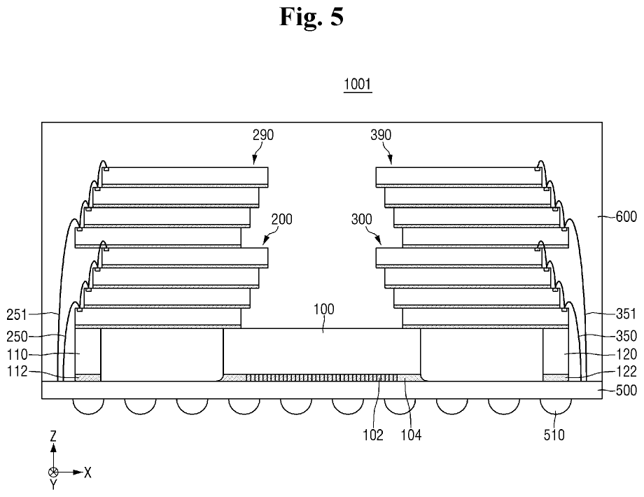

FIG. 1 is a plan view of a semiconductor package according to a first embodiment of the present disclosure. FIG. 2 is a cross-sectional view taken along line II-II of FIG. 1. FIG. 3 is an enlarged cross-sectional view of an area A of FIG. 2. FIG. 4 is an enlarged cross-sectional view of an area B of FIG. 2.

Referring to FIGS. 1 and 2, a semiconductor package 1000 includes a semiconductor chip 100, a first spacer 110, a second spacer 120, a first chip stack 200, a second chip stack 300, a substrate 500, and a mold layer 600.

The substrate 500 may be a package substrate, for example, and may include a base layer, which may be made of insulative or other material, one or more additional insulative layers, and one or more wiring layers, formed to transmit signals and voltage between the outside of the package 1000 and the semiconductor chips included in the package.

The semiconductor chip 100, the first spacer 110, and the second spacer 120 are disposed to be spaced apart from one another. For example, the first spacer 110, the semiconductor chip 100, and the second spacer 120 may be disposed to be spaced apart from one another in a first direction X (e.g., spaced apart from each other along a first directional axis). Specifically, the semiconductor chip 100 may be disposed in the middle of the center of the substrate 500, and the first and second spacers 110 and 120 may be disposed on opposite sides of the semiconductor chip 100. As illustrated in FIG. 1, the first spacer 110 may be disposed on one side (e.g., a first side) of the semiconductor chip 110 to be spaced apart from the semiconductor chip 110, and the second spacer 120 may be disposed on the other side (e.g., a second, opposite, side) of the semiconductor chip 110 to be spaced apart from the semiconductor chip 110. External connecting terminals 510 (e.g., solder bumps, grid arrays, or conductive tabs, also described as “external connection terminals” or “package-external connection terminals”) may be disposed below the substrate 500.

The semiconductor chip 100 may be provided in the form of a flip chip. Thus, multiple connecting terminals 102 may be disposed between the semiconductor chip 100 and the substrate 500. The connecting terminals 102, also described as “chip-external connection terminals,” are for electrically connecting the semiconductor chip 100 to wiring layers in the substrate 500. The connecting terminals 102 may be, for example, bumps, balls, or a combination thereof, but the present disclosure is not limited thereto.

An underfill 104 may be formed in the space between the semiconductor chip 100 and the substrate 500. The underfill 104 may be used for securing resistance against physical shock (e.g., drop shock), against temperature variations, and against thermal shock caused by temperature variations, for preventing electrical migration caused by dust/moisture absorption, and for dissipating heat.

The semiconductor chip 100 may be a controller for controlling chips (210 and 220) of a first chip stack 200 and chips (310 and 320) of a second chip stack 300.

As illustrated in FIG. 1, the first and second spacers 110 and 120 may extend lengthwise in a second direction Y, which is different from the first direction X, but the present disclosure is not limited thereto. An item, layer, or portion of an item or layer described as extending “lengthwise” in a particular direction has a length in the particular direction and a width perpendicular to that direction, where the length is greater than the width. The shape of the first and second spacers 110 and 120 is not particularly limited, as long as the first and second spacers 110 and 120 are capable of supporting the first and second chip stacks 200 and 300. The first and second spacers 110 and 120 may have a linear shape (or an “I” shape), as illustrated in FIG. 1, or may have, for example, a “T” shape or an “L” shape. The first and second spacers 110 and 120 may be referred to herein as supports, or support structures.

The first and second spacers 110 and 120 may be fixed on the substrate 500 by adhesive layers 112 and 122, respectively. The adhesive layers 112 and 122 may be, for example, adhesive films, but the present disclosure is not limited thereto.

The first and second spacers 110 and 120 may be dummy blocks, such as dummy chips, and/or may each be formed by a piece of semiconductor material, but the present disclosure is not limited thereto. For example, the first and second spacers 110 and 120 may be formed of an insulative material. The first and second spacers 110 and 120 may perform no electrical communication function, but may rather serve as a physical support structure. Each of the first spacer 110 and second spacer 120 may be described as a support block, or support post. A “block” as used in this physical sense refers to a three-dimensional structure having substantially flat top and bottom surfaces and having rigidity to support a structure formed thereon.

The first chip stack 200 may be disposed on the semiconductor chip 100 and the first spacer 110, and the second chip stack 300 may be disposed on the semiconductor chip 100 and the second spacer 120. For example, the first chip stack 200, the semiconductor chip 100, and the first spacer 110 may generally have a dolmen-like structure (or a stone gravel structure). The second chip 300, the semiconductor chip 100, and the second spacer 120 may generally have a dolmen-like structure.

The first chip stack 200 may have a structure in which a set of chips including multiple chips (e.g., the chips (210 and 220)) are stacked in a third direction Z. The chips (210 and 220) may be semiconductor chips, which may be memory chips, logic chips, or a combination thereof. Adhesive films (211 and 221) may be formed below the chips (210 and 220) to attach the chips (210 and 220) to their respective underlying members (e.g., lower chips, the first spacer 110, or the semiconductor chip 100). In some embodiments, the chips (210 and 220) may have a rectangular shape elongated in the second direction Y.

As illustrated in FIG. 2, the chips (210 and 220) may be stacked in the first chip stack 200 in the shape of a flight of stairs ascending to the right, to the left (if viewed from the opposite side), or toward the center of the semiconductor chip 100. Thus, the chips (210 and 220) may be stacked in the first chip stack 200 in the shape of a flight of stairs ascending toward a center of the semiconductor package 1000. Accordingly, pads (215 and 225) of the chips (210 and 220) may be exposed, and the exposed pads (215 and 225) may be electrically connected to the substrate 500 via wires 250. The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may generally have a planar surface area (often larger than a corresponding surface area of the internal wiring to which they are connected) to promote connection to a further terminal, such as a bump or solder ball, and/or an external wiring.

Similarly, the second chip stack 300 may have a structure in which a set of chips including multiple chips (e.g., the chips (310 and 320)) are stacked in the third direction Z. The chips (310 and 320) may be semiconductor chips, which may be memory chips, logic chips, or a combination thereof. Adhesive films (311 and 321) may be formed below the chips (310 and 320) to attach the chips (310 and 320) to their respective underlying members (e.g., lower chips, the second spacer 120, or the semiconductor chip 100). In some embodiments, the chips (310 and 320) may have a rectangular shape elongated in the second direction Y.

As illustrated in FIG. 2, the chips (310 and 320) may be stacked in the second chip stack 300 in the shape of a flight of stairs ascending to the left, to the right (if viewed from the opposite side), or toward the center of the semiconductor chip 100. Accordingly, pads (315 and 325) of the chips (310 and 320) may be exposed, and the exposed pads (315 and 325) may be electrically connected to the substrate 500 via wires 350.

As the chips (210 and 220) of the first chip stack 200 are connected to the substrate 500 via the wires 250 and the chips (310 and 320) of the second chip stack 300 are connected to the substrate 500 via the wires 350, which are different from the wires 250, the first and second chips stacks 200 and 300 may form different channels. The number of stacked chips in each of the first chip stack 200 and second chip stack 300 can be as shown in FIG. 2, or can be larger or smaller. For example, eight chips are shown in each stack, but four, or twelve, or another number, of chips may be included in each stack. Also, the first chip stack 200 and second chip stack 300 may have the same number of chips as each other, or may have a different number of chips from each other.

The top surfaces of the semiconductor chip 100, the first spacer 110, and the second spacer 120 may be positioned on the same plane. As the first chip stack 200 is formed on the semiconductor chip 100 and the first spacer 110 and the second chip stack 300 is formed on the semiconductor chip 100 and the second spacer 120, the first and second chip stacks 200 and 300 can be stably supported, when the top surfaces of the semiconductor chip 100, the first spacer 110, and the second spacer 120 are positioned on the same plane. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Referring to FIGS. 2 and 3, the semiconductor chip 100 includes a first edge area 101E, a center area 100C, and a second edge area 102E.

The center area 100C is an area including the center of the semiconductor chip 100, and the first and second edge areas 101E and 102E may be positioned near the center area 100C and on opposite sides of the center area 100C in the first direction X.

A first lowermost chip 210, which is one of the chips (210 and 220) of the first chip stack 200, may be positioned in the first edge area 101E of the semiconductor chip 100, but not in the center area 100C of the semiconductor chip 100.

A second lowermost chip 310, which is one of the chips (310 and 320) of the second chip stack 300, may be positioned in the second edge area 102E of the semiconductor chip 100, but not in the center area 100C of the semiconductor chip 100.

According to one embodiment, a width L11 of the first edge area 101E in the first direction X does not exceed ¼ of a width L1 of the semiconductor chip 100 in the first direction X from a side surface e1 of the semiconductor chip 100 in the first edge area 101E. In some embodiments, the width L11 is between about 1/20 and ¼ of the width L1. Furthermore, according to an embodiment, width L12 of the second edge area 102E does not exceed ¼ of a width L1 of the semiconductor chip 100 from a side surface e2 of the semiconductor chip 100 in the second edge area 102E. In some embodiments, the width L12 is between about 1/20 and ¼ of the width L1. Thus, the center area 100C may be larger than ½ of the width L1 of the semiconductor chip L1, and the first and second edge areas 101E and 102E may each be smaller than ¼ of the width L1 of the semiconductor chip 100. In some embodiments, the center area 100C can be as large as 9/10 of the width L1, and each of the first and second edge areas 101E and 102E may be as small as about 1/20 of the width L1. Accordingly, the distance between the first and second lowermost chips 210 and 310 (e.g., a closest distance, for example, in the first direction X) may be greater than ½ of the width L1 of the semiconductor chip 100, and in some cases, may be up to about 9/10 of the width L1. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In this manner, the influence of heat generated by the semiconductor chip 100 on the first and the second chip stacks 200 and 300 (particularly, the first and second lowermost chips 210 and 310) can be minimized.

Also, as the chips (210 and 220) of the first chip stack 200 are in the shape of a flight of stairs ascending to the right and the chips (310 and 320) of the second chip stack 300 are in the shape of a flight of stairs ascending to the left, the distance between first and second uppermost chips 220 and 320 of the first and second chip stacks 200 and 300 may be smaller than the distance between the first and second lowermost chips 210 and 310 of the first and second chip stacks 200 and 300. For example, space S1 between the first and second chip stacks 200 and 300 may become narrower from the bottom to the top thereof. Accordingly, heat generated by the semiconductor chip 100 may be quickly released in an upward direction (i.e., in the third direction Z) without considerably affecting the chips (210 and 220) of the first chip stack 200 and the chips (310 and 320) of the second chip stack 300.

In some embodiments, as noted above, the width L11 of the first edge area 101E, which overlaps with the first lowermost chip 210, may be greater than 1/20 (e.g., as small as 1/20) of the width L1 of the semiconductor chip 100, and the width L12 of the second edge area 102E, which overlaps with the second lowermost chip 310, may be greater than 1/20 (e.g., as small as 1/20) of the width L1 of the semiconductor chip 100. Accordingly, the first and second chip stacks 200 and 300 can be stably supported by the semiconductor chip 100.

Referring to FIGS. 2 and 4, a distance G2 between the semiconductor chip 100 and the first spacer 110 in the first direction X may be greater than ½ of a width L2 of the first lowermost chip 210.

If space S2 between the semiconductor chip 100 and the first spacer 110 becomes narrow due to the first spacer 110 having a large size, the mold layer 600 may not be able to properly fill the space S2 between the semiconductor chip 100 and the first spacer 110. However, as the distance G2 between the semiconductor chip 100 and the first spacer 110 is greater than ½ of the width of the first lowermost chip 210, the mold layer 600 can stably fill the space S2 between the semiconductor chip 100 and the first spacer 110.

The distance G2 between the semiconductor chip 100 and the first spacer 110 may be smaller than 9/10 of the width L2 of the first lowermost chip 210. Accordingly, the first chip stack 200 can be stably supported by the first spacer 110 and the semiconductor chip 100.

Although not specifically illustrated, the distance between the semiconductor chip 100 and the second spacer 210 may be greater than ½ of the width of the second lowermost chip 310 and smaller than 9/10 of the width of the second lowermost chip 310.

In short, as the first and second chip stacks 200 and 300 are formed on the semiconductor chip 100 and the first and second spacers 110 and 120 to have a dolmen-like structure, the size of the semiconductor package 1000 can be reduced. Also, the influence of heat generated by the semiconductor chip 100 on the first and second chip stacks 200 and 300 can be minimized by controlling the distance between the first and second lowermost chips 210 and 310 of the first and second chip stacks 200 and 300 (i.e., the size of the semiconductor chip 100 not being covered by the first and second lowermost chips 210 and 310). Also, the mold layer 600 can easily fill the spaces between the semiconductor chip 100 and the first and second spacers 110 and 120 by controlling the distances between the semiconductor chip 100 and the first and second spacers 110 and 120. As the semiconductor chip 100 and the first and second chip stacks 200 and 300 are effectively arranged in a limited space, the general performance of the semiconductor package 1000 can be maintained, even if the size of the semiconductor package 1000 is reduced.

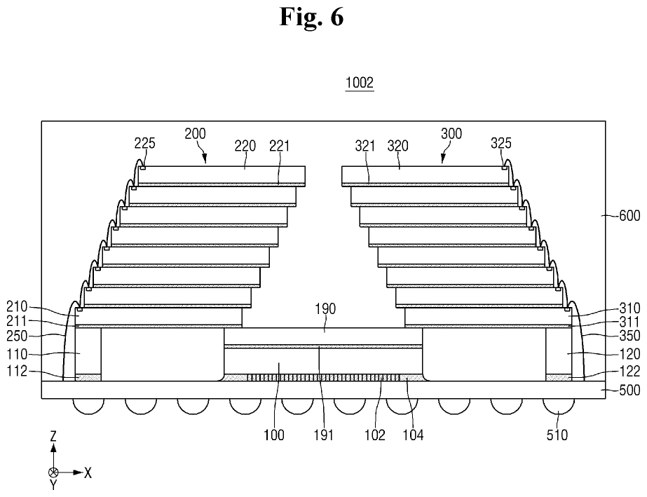

FIG. 5 is a cross-sectional view of a semiconductor package according to a second embodiment of the present disclosure. For convenience, the semiconductor package of FIG. 5 will hereinafter be described, focusing mainly on the differences with the semiconductor package of FIGS. 1 through 4.

Referring to FIG. 5, a semiconductor package 1001 further includes a third chip stack 290, which is formed on a first chip stack 200, and a fourth chip stack 390, which is formed on a second chip stack 300. It should be noted that ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first chip stack 200 includes chips that are stacked in the shape of a flight of stairs ascending to the right (e.g., toward a middle of the semiconductor package 1001) to expose pads, and the third chip stack 290 includes chips that are stacked on the first chip stack 200 in the shape of a flight of stairs ascending to the right (e.g., toward a middle of the semiconductor package 1001) to expose pads.

The chips of the first chip stack 200 are connected to a substrate 500 via first wires 250. The chips of the third chip stack 290 are connected to the substrate 500 via third wires 251, which are different from the first wires 250. Thus, the first and third chip stacks 200 and 290 may form different channels.

The second chip stack 300 includes chips that are stacked in the shape of a flight of stairs ascending to the left (e.g., toward a middle of the semiconductor package 1001) to expose pads, and the fourth chip stack 390 includes chips that are stacked on the second chip stack 300 in the shape of a flight of stairs ascending to the left (e.g., toward a middle of the semiconductor package 1001) to expose pads.

The chips of the second chip stack 300 are connected to the substrate 500 via second wires 350. The chips of the fourth chip stack 390 are connected to the substrate 500 via fourth wires 351, which are different from the second wires 350. Thus, the second and fourth chip stacks 300 and 390 may form different channels.

The distance between the lowermost chips of the first and second chip stacks 200 and 300 may be substantially the same as the distance between the lowermost chips of the third and fourth chip stacks 290 and 390, but the present disclosure is not limited thereto.

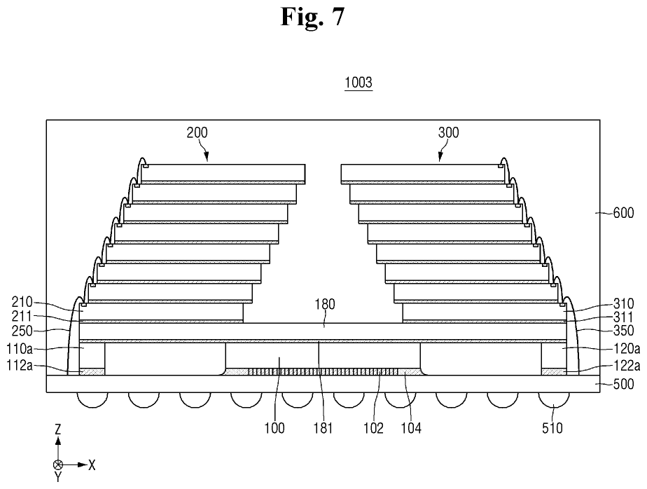

FIG. 6 is a cross-sectional view of a semiconductor package according to a third embodiment of the present disclosure. For convenience, the semiconductor package of FIG. 6 will hereinafter be described, focusing mainly on the differences with the semiconductor package of FIGS. 1 through 4.

Referring to FIG. 6, in a semiconductor package 1002, a first dummy chip 190 is disposed on a semiconductor chip 100. The first dummy chip 190 may be, for example, a silicon (Si) substrate, a silicon carbide (SiC), or a silicon germanium (SiGe) substrate, and may be described as a piece or block of semiconductor material (e.g., having no integrated circuit formed thereon), as a dummy substrate, or as a support structure, or dummy block. An adhesive film 191 may be formed between the first dummy chip 190 and the semiconductor chip 100.

A first chip stack 200 is disposed on the first dummy chip 190 and a first spacer 110, and a second chip stack 300 is disposed on the first dummy chip 190 and a second spacer 120. The top surface of the first dummy chip 190 may be positioned on the same plane as the top surfaces of the first and second spacers 110 and 120.

The semiconductor chip 100 and the first dummy chip 190 are illustrated as having the same width as each other, but the present disclosure is not limited thereto. Alternatively, for example, the width of the first dummy chip 190 may be greater than the width of the semiconductor chip 100.

Heat generated by the semiconductor chip 100 can be released through the first dummy chip 190 without being transmitted to the first and second chip stacks 200 and 300.

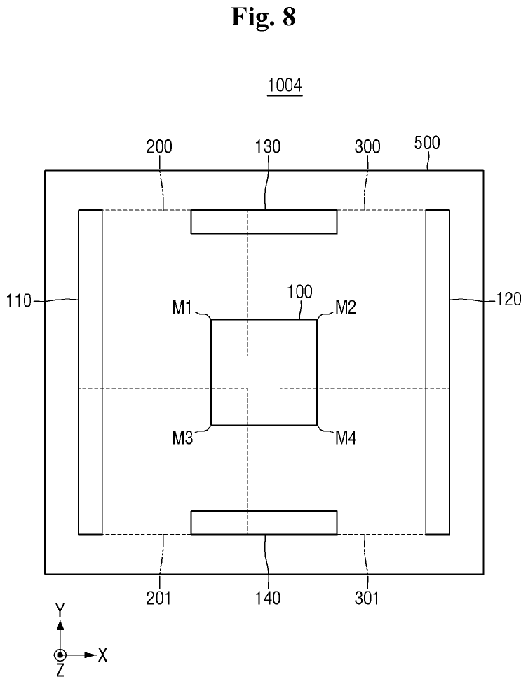

FIG. 7 is a cross-sectional view of a semiconductor package according to a fourth embodiment of the present disclosure. For convenience, the semiconductor package of FIG. 7 will hereinafter be described, focusing mainly on the differences with the semiconductor package of FIG. 6.

Referring to FIG. 7, a semiconductor package 1003 further includes a second dummy chip 180, which is disposed on a semiconductor chip 100 and first and second spacers 110a and 120a. An adhesive film 181 may be formed below the second dummy chip 180. Adhesive layers 112a and 122a are formed below the first and second spacers 110a and 120a to fix the first and second spacers 110a and 120a onto a substrate 500. A first chip stack 200 may be disposed on the second dummy chip 180, and a second chip stack 300 may be disposed on the second dummy chip 180 to be spaced apart from the first chip stack 200. As the second dummy chip 180 extends to be disposed not only on the top surface of the semiconductor chip 100, but also on the first and second spacers 110a and 120b, heat generated by the semiconductor chip 100 can be released through the second dummy chip 180 without being transmitted to the first and second chip stacks 200 and 300. The second dummy chip 180 may be described as a piece or block of semiconductor material (e.g., having no integrated circuit formed thereon), as a dummy substrate, or as a support structure, or dummy block.

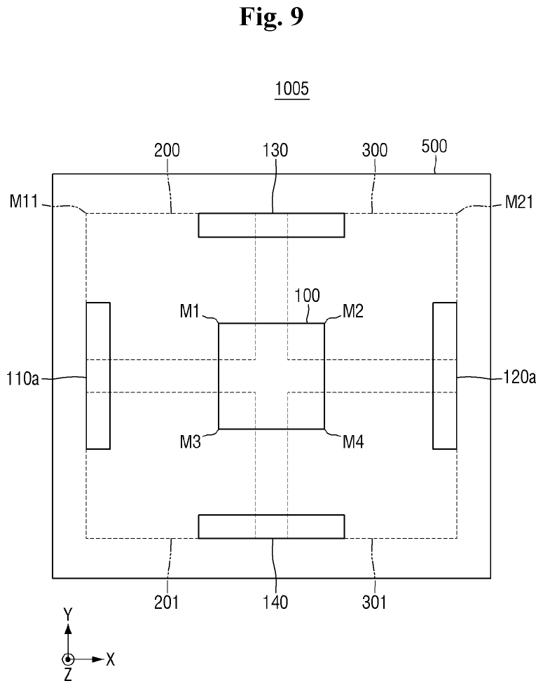

FIG. 8 is a cross-sectional view of a semiconductor package according to a fifth embodiment of the present disclosure. For convenience, the semiconductor package of FIG. 8 will hereinafter be described, focusing mainly on the differences with the semiconductor package of FIGS. 1 through 4.

Referring to FIG. 8, a semiconductor package 1004 includes a first chip stack 200, a second chip stack 300, a fifth chip stack 201, and a sixth chip stack 301.

A semiconductor chip 100 has four apexes, or corners M1, M2, M3, and M4. The first chip stack 200 may be positioned on the first apex M1, the second chip stack 300 may be positioned on the second apex M2, the fifth chip stack 201 may be positioned on the third apex M3, and the sixth chip stack 301 may be positioned on the fourth apex M4.

A first spacer 110 may be positioned below the first and fifth chip stacks 200 and 201 to overlap the first and fifth chip stacks 200 and 201 from a plan view, and may extend in a second direction Y.

A second spacer 120 may be positioned below the second and sixth chip stacks 300 and 301 to overlap the second and sixth chip stacks 300 and 301 from a plan view, and may extend in the second direction Y.

A third spacer 130 may be positioned below the first and second chip stacks 200 and 300 to overlap the first and second chip stacks 200 and 300 from a plan view, and may extend in a first direction X.

A fourth spacer 140 may be positioned below the fifth and sixth chip stacks 201 and 301 to overlap the fifth and sixth chip stacks 201 and 301 from a plan view, and may extend in the first direction X.

FIG. 8 illustrates that opposite ends, in the second direction Y, of the first spacer 110 are aligned with ends of the first and fifth chip stacks 200 and 201, but the present disclosure is not limited thereto. FIG. 8 also illustrates that opposite ends, in the second direction Y, of the second spacer 120 are aligned with ends of the second and sixth chip stacks 300 and 301, but the present disclosure is not limited thereto. Each chip stack depicted in FIG. 8 can be any of the various chip stacks described herein, and can be oriented in any of four directions (e.g., as shown in the various embodiments, or rotated 90, 180, or 270 degrees.

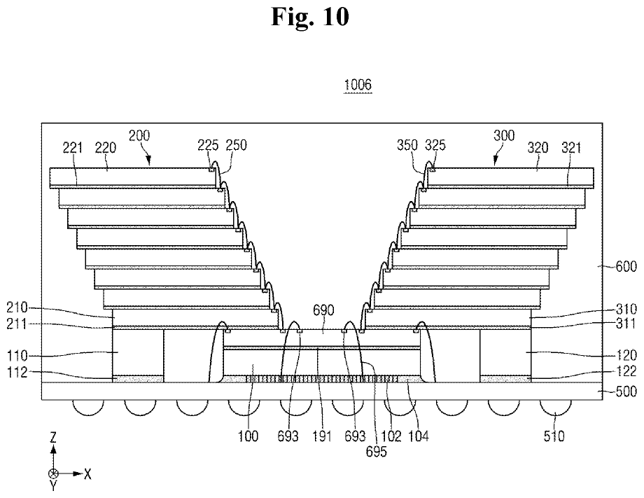

FIG. 9 is a cross-sectional view of a semiconductor package according to a sixth embodiment of the present disclosure. For convenience, the semiconductor package of FIG. 9 will hereinafter be described, focusing mainly on the differences with the semiconductor package of FIG. 8.

Referring to FIG. 9, first and second spacers 110a and 120a of a semiconductor package 1005 may be shorter than the first and second spacers 110 and 120 of FIG. 9.

As the first spacer 110a is relatively short, three apexes (e.g., corners) of a first chip stack 200 are supported by the first spacer 110a, a third spacer 130, and a semiconductor chip 100. Thus, no particular supporting member is present below the other apex of the first chip stack 200, i.e., an apex M11, and as a result, a space is provided below the apex M11 of the first chip stack 200. Accordingly, a mold layer 600 can easily fill the space below the first chip stack 200 with the use of the space below the apex M11.

Similarly, as the second spacer 120a is relatively short, three apexes (e.g., corners) of a second chip stack 300 are supported by the second spacer 120a, the third spacer 130, and the semiconductor chip 100. Thus, no particular supporting member is present below the other apex of the second chip stack 300, i.e., an apex M21, and as a result, a space is provided below the apex M21 of the second chip stack 300. Accordingly, the mold layer 600 can easily fill the space below the second chip stack 300 with the use of the space below the apex M21.

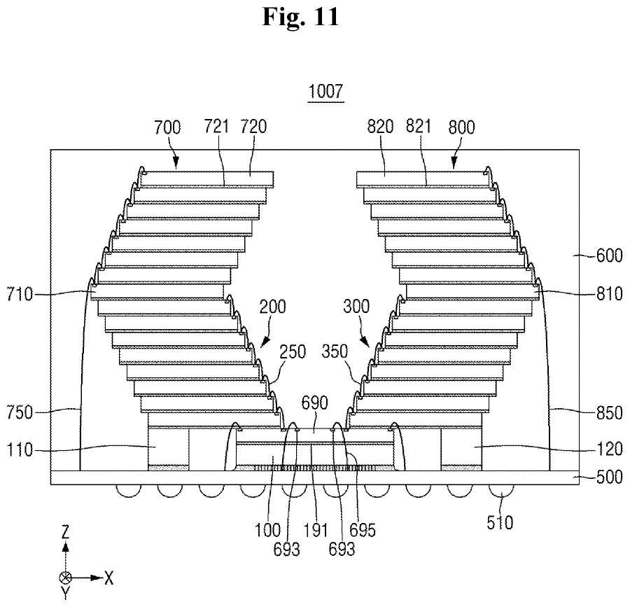

FIG. 10 is a cross-sectional view of a semiconductor package according to a seventh embodiment of the present disclosure. For convenience, the semiconductor package of FIG. 10 will hereinafter be described, focusing mainly on the differences with the semiconductor package of FIGS. 1 through 4.

Referring to FIG. 10, in a semiconductor package 1006, a buffer chip 690 is disposed on a semiconductor chip 100. As already mentioned above, the semiconductor chip 100 may be a flip chip. On the contrary, the buffer chip 690 may be disposed to expose pads 693, which are formed on the top surface of the buffer chip 690. An adhesive film 191 may be disposed between the semiconductor chip 100 and the buffer chip 690.

The semiconductor chip 100 and the buffer chip 690 are illustrated as having the same width in the first direction X, but the present disclosure is not limited thereto. Alternatively, the width in the first direction X of the buffer chip 690 may be greater than the width in the first direction X of the semiconductor chip 100. Ends in the second direction Y of the buffer chip 690 may extend beyond respective ends of chips of the first chip stack 200 and second chip stack 300 in the second direction Y, so that the wires 695 can be connected to certain pads 693 of the buffer chip 690.

A first chip stack 200 may be disposed on a first spacer 110 and the buffer chip 690, and a second chip stack 300 may be disposed on a second spacer 120 and the buffer chip 690. The top surfaces of the buffer chip 690, the first spacer 110, and the second spacer 120 may be positioned on the same plane.

As illustrated in FIG. 10, chips (210 and 220) of the first chip stack 200 may be stacked in the shape of a flight of stairs ascending to the left (i.e., toward the outside of a substrate 500). Pads 225 of the chips (210 and 220) are exposed, and the exposed pads 225 are electrically connected to the pads 693 of the buffer chip 690 via wires 250. The pads 693 are electrically connected to the substrate 500 via wires 695. As illustrated in FIG. 10, a lowermost chip 210 of the first chip stack 200 and the buffer chip 690 (e.g., pads of the lowermost chip 210 and pads of the buffer chip 690) may be directly electrically connected, for example by single wires of the wires 250 (as opposed to higher level chips 210 of the first chip stack 200, whose pads may be connected to pads of the buffer chip 690 using a plurality of wires).

Chips (310 and 320) of the second chip stack 300 may be stacked in the shape of a flight of stairs ascending to the right (i.e., toward the outside of a substrate 500). Pads 325 of the chips (310 and 320) are exposed, and the exposed pads 325 are electrically connected to the pads 693 of the buffer chip 690 via wires 350. The pads 693 are electrically connected to the substrate 500 via the wires 695. As illustrated in FIG. 10, a lowermost chip 310 of the second chip stack 300 and the buffer chip 690 may be directly connected by the wires 350 in a similar manner as described above in connection with the first chip stack 200.

As the wires 250 and the wires 350 are disposed on the inside of the first and second chip stacks 200 and 300 (i.e., in the space between the first and second chip stacks 200 and 300), the size of the semiconductor package 1006 can be reduced, as compared to a case where the wires 250 and the wires 350 are disposed on the outside of the first and second chip stacks 200 and 300, because the semiconductor package 1006 has a structure in which the wires 250 and the wires 350 are connected to the substrate 500 through the buffer chip 690. Thus, various devices (i.e., the semiconductor chip 100 and the first and second chip stacks 200 and 300) can be effectively arranged in the limited space of the semiconductor package 1006.

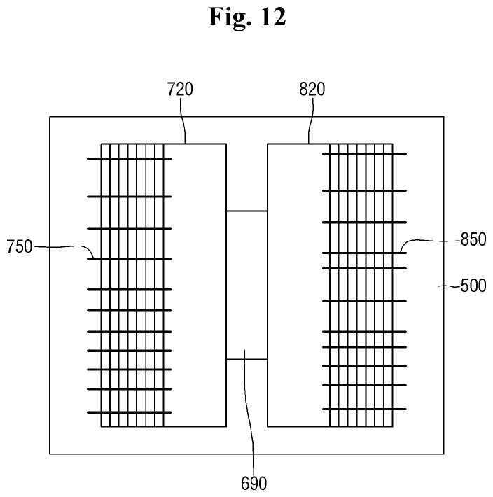

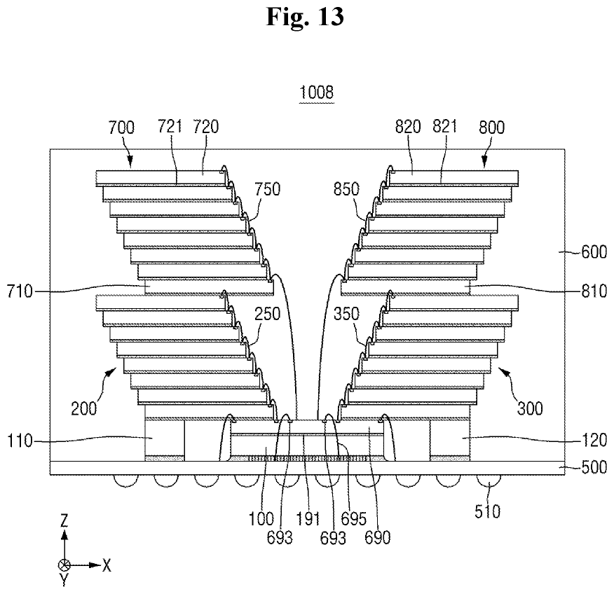

FIG. 11 is a cross-sectional view of a semiconductor package according to an eighth embodiment of the present disclosure. FIG. 12 is a plan view of the semiconductor package of FIG. 11. For convenience, the semiconductor package of FIG. 12 will hereinafter be described, focusing mainly on the differences with the semiconductor package of FIG. 10.

Referring to FIGS. 11 and 12, in a semiconductor package 1007, a seventh chip stack 700 is disposed on a first chip stack 200. Chips (710 and 720) of the seventh chip stack 700 may be stacked in the shape of a flight of stairs ascending to the right (i.e., toward the center of a substrate 500). Pads of the chips (710 and 720) are electrically connected to the substrate 500 via wires 750. The wires 750 may be disposed on the outside of the first chip stack 200.

In the semiconductor package 1007, an eighth chip stack 800 is disposed on a second chip stack 300. Chips (810 and 820) of the eighth chip stack 800 may be stacked in the shape of a flight of stairs ascending to the left (i.e., toward the center of a substrate 500). Pads of the chips (810 and 820) are electrically connected to the substrate 500 via wires 850. The wires 850 may be disposed on the outside of the second chip stack 300. It should be noted that combined chip stacks stacked directly on each other can be referred to together herein as a single chip stack. For example chip stack 200 and chip stack 700 may be described as a single chip stack, having, for example, a first portion of the stack (e.g., chip stack 200), stacked in the shape of a flight of stairs ascending in a first direction (e.g., to the left), and a second portion of the stack (e.g., chip stack 700), stacked in the shape of a flight of stairs ascending in a second direction (e.g., to the right) opposite the first direction. The chip stack formed of the first chip stack 200 and seventh chip stack 700 may have a chevron shape. Similarly, the chip stack formed of the second chip stack 300 and the eighth chip stack 800 may have a chevron shape oriented in the opposite direction.

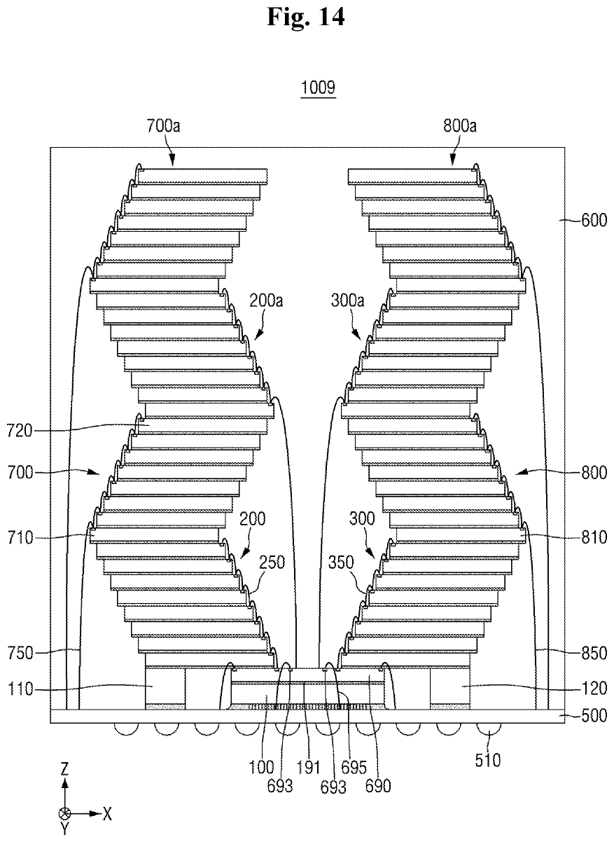

FIG. 13 is a cross-sectional view of a semiconductor package according to a ninth embodiment of the present disclosure. For convenience, the semiconductor package of FIG. 13 will hereinafter be described, focusing mainly on the differences with the semiconductor package of FIGS. 11 and 12.

Referring to FIG. 13, in a semiconductor package 1008, a seventh chip stack 700 is disposed on a first chip stack 200. Chips (710 and 720) of the seventh chip stack 700 may be stacked in the shape of a flight of stairs ascending to the left (i.e., toward the outside of a substrate 500). Pads of the chips (710 and 720) are electrically connected to a buffer chip 690 via wires 750. The chip stack formed by first chip stack 200 and seventh chip stack 700 may be described as having a lightning bolt shape.

In the semiconductor package 1008, an eighth chip stack 800 is disposed on a second chip stack 300. Chips (810 and 820) of the eighth chip stack 800 may be stacked in the shape of a flight of stairs ascending to the right (i.e., toward the outside of a substrate 500). The chip stack formed by second chip stack 300 and eighth chip stack 800 may be described as having a lightning bolt shape. Pads of the chips (810 and 820) are electrically connected to the buffer chip 690 via wires 850.

The wires 750 and the wires 850 are disposed on the inside of the first and second chip stacks 200 and 300 (i.e., in the space between the first and second chip stacks 200 and 300). The size of the semiconductor package 1008 can be reduced, as compared to a case where the wires 750 and the wires 850 are disposed on the outside of the first and second chip stacks 200 and 300.

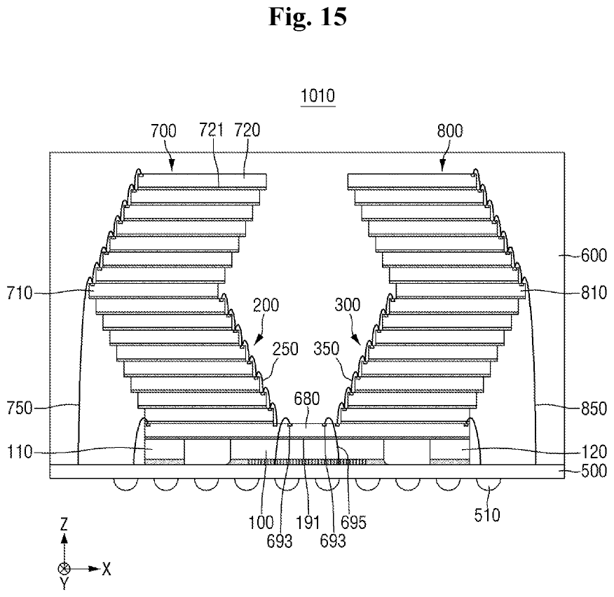

FIG. 14 is a cross-sectional view of a semiconductor package according to a tenth embodiment of the present disclosure.

Referring to FIG. 14, in a semiconductor package 1009, chip stacks 700, 200a, and 700a are sequentially stacked on a chip stack 200, and chip stacks 800, 300a, and 800a are sequentially stacked on a chip stack 300.

Chips of each of the chip stacks 200, 300, 200a, and 300a may be stacked in the shape of a flight of stairs ascending toward the outside of a substrate 500, and wires connected to the chip stacks 200, 300, 200a, and 300a may be connected to a buffer chip 695 and may be connected at the inside of the chip stacks (e.g., between the chip stacks).

Chips of each of the chip stacks 700, 800, 700a, and 800a may be stacked in the shape of a flight of stairs ascending toward the center of the substrate 500, and wires connected to the chip stacks 200, 300, 200a, and 300a may be connected to the substrate 500 and may be connected at the outside of the chip stacks. Chip stacks 200, 700, 200a, and 700a may have a zig zag shape, and chip stacks 300, 800, 300a, and 800a may also have a zig zag shape.

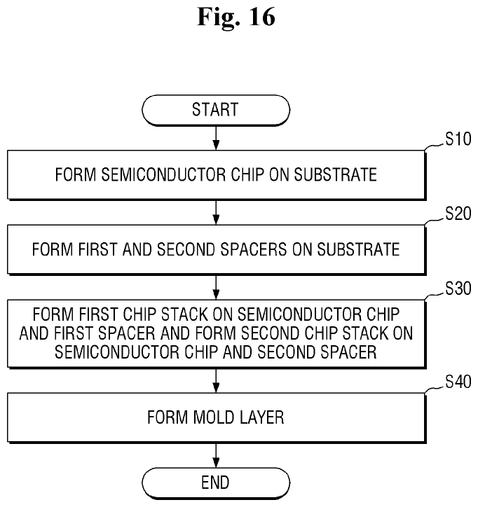

FIG. 15 is a cross-sectional view of a semiconductor package according to an eleventh embodiment of the present disclosure.

Referring to FIG. 15, in a semiconductor package 1010, a buffer chip 680 may extend over to the top surfaces of first and second spacers 110 and 120.

A first chip stack 200 may be disposed on the buffer chip 680, and a second chip stack 300 may be disposed on the buffer chip 680 to be spaced apart from the first chip stack 200. As the buffer chip 680 extends to be disposed not only on the top surface of a semiconductor chip 100, but also on the top surfaces of the first and second spacers 110 and 120, the arrangement of wires (250, 350, and 695) can be simplified.

A method of fabricating the semiconductor package according to the first embodiment will hereinafter be described with reference to FIGS. 1 through 4 and 16 through 19.

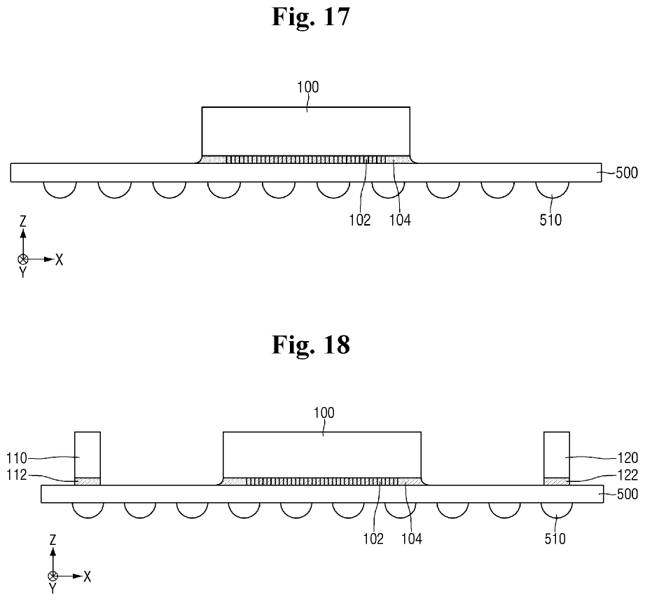

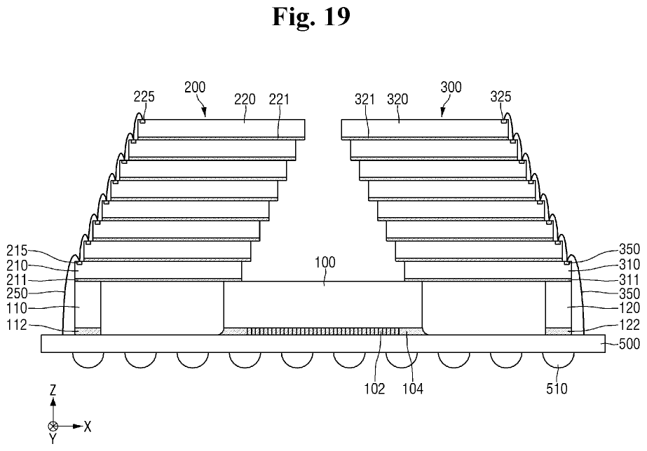

FIG. 16 is a block diagram illustrating a method of fabricating the semiconductor package according to the first embodiment. FIGS. 17 through 19 are cross-sectional views illustrating intermediate steps of the method of FIG. 16.

Referring to FIGS. 16 and 17, a semiconductor chip 100 is formed on a substrate 500 (S10).

Specifically, a plurality of connecting terminals 102 are formed on a surface of the semiconductor chip 100, and the semiconductor chip 100 is turned upside down and is then attached on the substrate 500 in the form of a flip chip. Thereafter, the space between the semiconductor chip 100 and the substrate 500 may be filled with an underfill 104.

Thereafter, referring to FIGS. 16 and 18, first and second spacers 110 and 120 are formed on the substrate 500 to be spaced apart from the semiconductor chip 100 (S20).

Specifically, adhesive layers 112 and 122 are formed below the first and second spacers 110 and 120, respectively, to fix the first and second spacers 110 and 120 onto the substrate 500.

Thereafter, referring to FIGS. 16 and 19, a first chip stack 200 is formed on the semiconductor chip 100 and the first spacer 110, and a second chip stack 300 is formed on the semiconductor chip 100 and the second spacer 120 (S30).

Specifically, the semiconductor chip 100 includes a center area 100C (of FIG. 3), a first edge area 101E (of FIG. 3), which is disposed on one side of the center area 100C, and a second edge area 102E (of FIG. 3), which is disposed on the other side of the center area 100C.

A first lowermost chip 210 of the first chip stack 200 may be positioned on the first edge area 101E of the semiconductor chip 100, but not on the center area 100C of the semiconductor chip 100. In other words, the first lowermost chip 210 may overlap with the first edge area 101E, but not with the center area 100C.

A second lowermost chip 310 of the second chip stack 300 may be positioned on the second edge area 102E of the semiconductor chip 100, but not on the center area 100C of the semiconductor chip 100. In other words, the second lowermost chip 310 may overlap with the second edge area 102E, but not with the center area 100C. For each chip stack (200 and 300), the entire chip stack may be formed first and placed on the semiconductor chip 100 and respective spacer (110 or 120), or the chip stack may be formed by disposing one chip at a time on the semiconductor chip 100 and respective spacer (110 or 120). Also, for each chip stack (200 or 300), if chips are disposed one chip at a time, the wires (250 or 350) may be formed after each chip is disposed, after a group of chips are disposed, or after all of the chips are disposed.

In some embodiments, the distance between the first and second lowermost chips 210 and 310 may be greater than ½ of the width of the semiconductor chip 100.

In some embodiments, the distance between the semiconductor chip 100 and the first spacer 110 may be greater than ½ of the width of the first lowermost chip 210. The distance between the semiconductor chip 100 and the second spacer 120 may be greater than ½ of the width of the second lowermost chip 310.

The distance between a first uppermost chip 220 of the first chip stack 200 and a second uppermost chip 320 of the second chip stack 300 may be smaller than the distance between the first and second lowermost chips 210 and 310.

Thereafter, referring to FIG. 16 and further to FIG. 2, a mold layer 600 is formed on the structure illustrated in FIG. 19.

Although not specifically illustrated, a first dummy chip 190 may be formed on the semiconductor chip 100 before the formation of the first and second chip stacks 200 and 300, i.e., S30, thereby obtaining the semiconductor package 1002 of FIG. 6.

In this case, in S30, the first chip stack 200 is formed on the first dummy chip 190 and the first spacer 110, and the second chip stack 300 is formed on the first dummy chip 190 and the second spacer 120.

Although not specifically illustrated, a second dummy chip 180 may be formed on the semiconductor chip 100, the first spacer 110, and the second spacer 120 before the formation of the first and second chip stacks 200 and 300, i.e., S30, thereby obtaining the semiconductor package 1003 of FIG. 7.

In this case, in S30, the first chip stack 200 may be formed on the second dummy chip 180, and the second chip stack 300 may be formed on the first dummy chip 190.

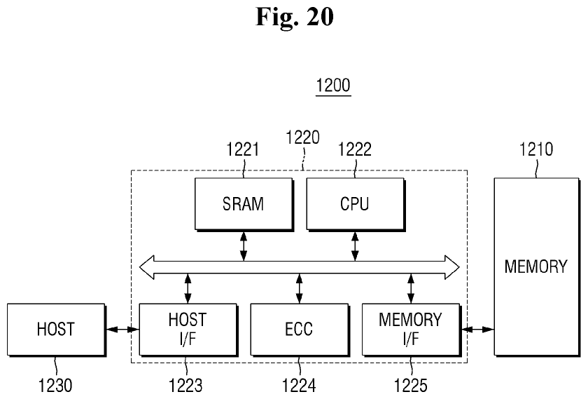

FIG. 20 is a block diagram of a memory card including a semiconductor package according to some embodiments of the present disclosure.

Referring to FIG. 20, the semiconductor packages 1000 through 1005 may be applied to a memory card 1200.

The memory card 1200 may include a memory controller 1220, which controls the exchange of data between a host 1230 and a memory 1210. A static random access memory (SRAM) 1221 may be used as an operation memory of a central processing unit (CPU) 1222. A host interface 1223 may execute the data exchange protocol of the host 1230, which is connected to the memory card 1200. An error correction code (ECC) engine 1224 may detect and correct errors included in data read from the memory 1210. A memory interface 1225 may interface with memory 1210. The CPU 1222 may perform various control operations for a data exchange operation of the memory controller 1220.

For example, at least one of the memory 1210 and the CPU 1222 may include at least one of the semiconductor packages 1000 through 1005.

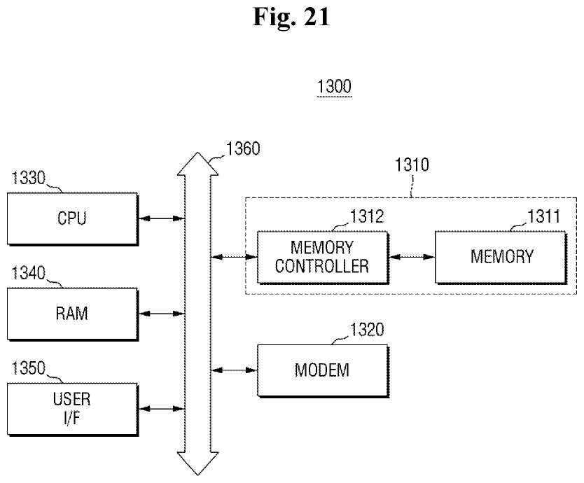

FIG. 21 is a block diagram of an information processing system to which a semiconductor package according to some embodiments of the present disclosure is applied.

Referring to FIG. 21, the semiconductor packages 1000 through 1005 may be applied to an information processing system 1300.

Examples of the information processing system 1300 include a mobile device, a computer, and the like. The information processing system 1300 may include a memory system 1310, a modem 1320, a CPU 1330, a random access memory (RAM) 1340, and a user interface 1360, which are electrically connected to a system bus 1360. The memory system 1310 may include a memory 1311 and a memory controller 1312 and may have substantially the same configuration as the memory card 1200 of FIG. 20. At least one of the CPU 1330 and the RAM 1340 may include at least one of the semiconductor packages 1000 through 1005.

Data processed by the CPU 1330 or input from outside the memory system 1310 may be stored in the memory system 1310. The information processing system 1300 may be provided as a memory card, a solid-state disk (SSD), a camera image sensor, or an application chipset. For example, the memory system 1310 may be implemented as an SSD, in which case, the information processing system 1300 can store a large amount of data in the memory system 1310 stably and reliably.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

1. A semiconductor package comprising:
a substrate;
a semiconductor chip formed on the substrate, the semiconductor chip including a center area, a first edge area, which is disposed on a first side of the center area with respect to a first directional axis, and a second edge area, which is disposed on a second side of the center area opposite the first side with respect to the first directional axis;
a first spacer formed on the substrate and spaced apart from the semiconductor chip in a direction along the first directional axis;
a second spacer formed on the substrate and spaced apart from the semiconductor chip in a direction along the first directional axis;
a first chip stack disposed on the semiconductor chip and the first spacer; and
a second chip stack disposed on the semiconductor chip and the second spacer,
wherein
a lowermost chip of the first chip stack is positioned on the first edge area of the semiconductor chip, but not on the center area of the semiconductor chip, and
a lowermost chip of the second chip stack is positioned on the second edge area of the semiconductor chip, but not on the center area of the semiconductor chip.

2. The semiconductor package of claim 1, wherein a distance in a direction along the first directional axis between the lowermost chip of the first chip stack and the lowermost chip of the second chip stack is greater than ½ of a width in a direction along the first directional axis of the semiconductor chip.

3. The semiconductor package of claim 1, wherein a distance in a direction along the first directional axis between the semiconductor chip and the first spacer is greater than ½ of a width in a direction along the first directional axis of the lowermost chip of the first chip stack.

4. The semiconductor package of claim 1, wherein a distance in a direction along the first directional axis between an uppermost chip of the first chip stack and an uppermost chip of the second chip stack is smaller than a distance in a direction along the first directional axis between the lowermost chip of the first chip stack and the lowermost chip of the second chip stack.

5. The semiconductor package of claim 1, further comprising:
a dummy chip disposed on the semiconductor chip,
wherein
the first chip stack is disposed on the dummy chip and the first spacer, and
the second chip stack is disposed on the dummy chip and the second spacer.

6. The semiconductor package of claim 5, wherein top surfaces of the dummy chip, the first spacer, and the second spacer are positioned on the same plane.

7. The semiconductor package of claim 1, further comprising:
a dummy chip disposed on the semiconductor chip, the first spacer, and the second spacer,
wherein
the first chip stack is disposed on the dummy chip, and
the second chip stack is disposed on the dummy chip to be spaced apart from the first chip stack.

8. The semiconductor package of claim 1, further comprising:
a buffer chip disposed on the semiconductor chip, the buffer chip having multiple pads formed on a top surface thereof,
wherein
the first chip stack is disposed on the first spacer and the buffer chip,
the second chip stack is disposed on the second spacer and the buffer chip, and
a first chip of the first chip stack is connected to a first pad, which is one of the multiple pads, via a first wire.

9. The semiconductor package of claim 8, wherein in the first chip stack, multiple chips are stacked in the shape of a flight of stairs ascending in a direction toward the outside of the substrate.

10. The semiconductor package of claim 8, wherein a first chip of the second chip stack is connected to a second pad, which is another one of the multiple pads, via a second wire.

11. The semiconductor package of claim 8, further comprising:
a third chip stack disposed on the first chip stack,
wherein
in the third chip stack, multiple chips are stacked in the shape of a flight of stairs ascending in a direction toward the center area of the semiconductor chip, and
a first chip of the third chip stack is directly electrically connected to the substrate via a single wire.

12. The semiconductor package of claim 8, further comprising:
a third chip stack disposed on the first chip stack,
wherein
in the third chip stack, multiple chips are stacked in the shape of a flight of stairs ascending in a direction toward the outside of the substrate, and
a first chip of the third chip stack is directly electrically connected to a second pad, which is another one of the multiple pads, via a single wire.

13. The semiconductor package of claim 8, wherein
the buffer chip extends along the first directional axis to top surfaces of the first and second spacers,
the first chip stack is disposed on the buffer chip, and
the second chip stack is disposed on the buffer chip to be spaced apart from the first chip stack along the first directional axis.

14. The semiconductor package of claim 1, wherein
each of the first and second chip stacks has a respective set of chips including multiple memory chips stacked therein, and
the semiconductor chip is a controller for controlling each set of chips.

15. The semiconductor package of claim 1, wherein
the semiconductor chip has first through fourth corners,
the first chip stack is positioned on the first corner,
the second chip stack is positioned on the second corner, and
the semiconductor package further comprises third and fourth chip stacks positioned on the third and fourth corners, respectively.

16. The semiconductor package of claim 15, wherein
the first spacer is positioned below the first and third chip stacks to overlap the first and third chip stacks from a plan view,
the second spacer is positioned below the second and fourth chip stacks to overlap the second and fourth chip stacks from a plan view, and
the semiconductor package further comprises a third spacer positioned below the first and second chip stacks to overlap the first and second chip stacks from a plan view and a fourth spacer positioned below the third and fourth chip stacks to overlap the third and fourth chip stacks from a plan view.

17. A semiconductor package comprising:
a substrate;
a semiconductor chip including a center area, a first edge area, which is disposed on a first side of the center area, and a second edge area, which is disposed on a second side of the center area opposite the first side, the semiconductor chip being in the form of a flip chip;
a plurality of bumps disposed between the semiconductor chip and the substrate;
an underfill filling space between the substrate and the semiconductor chip;
a first support block disposed on the substrate to be spaced apart from a first side of the semiconductor chip;
a second support block disposed on the substrate to be spaced apart from the a second side of the semiconductor chip opposite the first side;
a first chip stack disposed on the first edge area of the semiconductor chip and the first support block; and
a second chip stack disposed on the second edge area of the semiconductor chip and the second support block,
wherein
a distance between a lowermost chip of the first chip stack and a lowermost chip of the second chip stack is greater than ½ of a width of the semiconductor chip, and
a distance between the semiconductor chip and the first support block is greater than ½ of a width of the lowermost chip of the first chip stack.

18. The semiconductor package of claim 17, wherein a distance between an uppermost chip of the first chip stack and an uppermost chip of the second chip stack is smaller than the distance between the lowermost chip of the first chip stack and the lowermost chip of the second chip stack.

19. The semiconductor package of claim 17, wherein the first support block is a first dummy chip and the second support block is a second dummy chip, and further comprising:
a third dummy chip disposed on the semiconductor chip,
wherein
the first chip stack is disposed on the first and third dummy chips, and
the second chip stack is disposed on the second and third dummy chips.

20-21. (canceled)

22. A method of fabricating a semiconductor package, comprising:
disposing a semiconductor chip on a substrate, the semiconductor chip including a center area, a first edge area, which is disposed on a first side of the center area, and a second edge area, which is disposed on a second side of the center area opposite the first side;
disposing first and second spacers on the substrate to be spaced apart from the semiconductor chip; and
disposing a first chip stack on the semiconductor chip and the first spacer and disposing a second chip stack on the semiconductor chip and the second spacer,
wherein disposing the first chip stack on the semiconductor chip and the first spacer and disposing a second chip stack on the semiconductor chip and the second spacer includes:
positioning a lowermost chip of the first chip stack on the first edge area of the semiconductor chip, but not on the center area of the semiconductor chip, and
positioning a second lowermost chip of the second chip stack on the second edge area of the semiconductor chip, but not on the center area of the semiconductor chip.

23-27. (canceled)
